(19) United States
(12) Patent Application Publication
(10) Pub. No.: US 2025/0105224 A1
(43) Pub. Date: Mar. 27, 2025

(54) PACKAGE STRUCTURE AND METHOD FOR FORMING SAME

(71) Applicant: JCET MANAGEMENT CO., LTD., Shanghai (CN)

(72) Inventor: Cheng YANG, Shanghai (CN)

(73) Assignee: JCET MANAGEMENT CO., LTD., Shanghai (CN)

(21) Appl. No.: 18/888,135

(22) Filed: Sep. 17, 2024

(30) Foreign Application Priority Data
Sep. 21, 2023 (CN) 202311228936.5

(51) Int. Cl. H01L 25/10; H01L 21/48; H01L 23/00; H01L 23/31; H01L 23/49; H01L 23/498; H01L 25/00

(52) U.S. Cl. CPC H01L 25/105; H01L 21/4853; H01L 23/49; H01L 23/49816; H01L 24/16; H01L 24/32; H01L 24/73; H01L 25/50; H01L 23/3107; H01L 2224/16145; H01L 2224/16245; H01L 2224/32145; H01L 2224/32225; H01L 2224/73204; H01L 2224/73253; H01L 2225/1041

(57) ABSTRACT

A package structure and a method for forming the same are disclosed. In the method for forming the package structure, a first bonding layer and a plurality of protruded metal pillars are formed on an upper surface of a carrier plate; a first chip including a first functional face and a first back face that are opposite to each other is provided, where a plurality of first external connection terminals are arranged on the first functional face, and a second bonding layer is arranged on the first back face; the second bonding layer is bonded to the first bonding layer; a first molding layer configured to mold the first chip and the metal pillars is provided; a second chip including a second functional face and a second back face that are opposite to each other is provided, and the second chip is flip-mounted on the first molding layer.

### CROSS REFERENCE TO RELATED APPLICATION

The present application is based upon and claims priority to Chinese Patent Application No. CN202311228936.5, filed on Sep. 21, 2023, the entire disclosure of which is incorporated herein by reference for all purposes.

### TECHNICAL FIELD

The present disclosure relates to the technical field of semiconductor packaging, and in particular, relates to a package structure and a method for forming the same.

### BACKGROUND

An embedded multi-die interconnect bridge (EMIB) is one of conventional advanced packaging technologies.

Similar to 2.5D packaging based on silicon interposers, EMIB packaging achieves localized high-density interconnection via silicon bridges. Compared to traditional 2.5D packaging, EMIB packaging has several advantages, such as standard packaging yields, smaller size, no need for through-silicon vias (TSVs), no additional processes, and simpler design.

However, during the EMIB packaging process, the embedded chips are prone to positional shifts.

### SUMMARY

Some embodiments of the present disclosure provide a method for forming a package structure. The method includes:
providing a carrier plate;
forming a first bonding layer and a plurality of protruded metal pillars on an upper surface of the carrier plate;
providing a first chip including a first functional face and a first back face that are opposite to each other, wherein a plurality of first external connection terminals are arranged on the first functional face, and a second bonding layer is arranged on the first back face;
bonding the second bonding layer on the first back face of the first chip to the first bonding layer on the upper surface of the carrier plate;
forming a first molding layer configured to mold the first chip and the plurality of protruded metal pillars, wherein the first molding layer exposes top surfaces of the plurality of first external connection terminals and the plurality of protruded metal pillars;
providing a second chip including a second functional face and a second back face that are opposite to each other, wherein a plurality of second external connection terminals are arranged on the second functional face;
flip-mounting the second chip on the first molding layer, wherein the plurality of second external connection terminals on the second chip are electrically connected to the top surfaces of the plurality of first external connection terminals and the plurality of protruded metal pillars;
forming a second molding layer configured to mold the second chip on the first molding layer;
removing the carrier plate and the first bonding layer to expose bottom surfaces of the plurality of protruded metal pillars and a surface of the second bonding layer on the first back face of the first chip; and
forming external connection bumps connected to the plurality of protruded metal pillars on the bottom surfaces of the plurality of protruded metal pillars.

Some embodiments of the present disclosure further provide a package structure. The package structure includes:
a carrier plate;
a first bonding layer and a plurality of protruded metal pillars on an upper surface of the carrier plate;
a first chip including a first functional face and a first back face that are opposite to each other, wherein a plurality of first external connection terminals are arranged on the first functional face, and a second bonding layer is arranged on the first back face, wherein the second bonding layer on the first back face of the first chip is bonded to the first bonding layer on the upper surface of the carrier plate;
a first molding layer configured to mold the first chip and the plurality of protruded metal pillars, wherein the first molding layer exposes top surfaces of the plurality of first external connection terminals and the plurality of protruded metal pillars;
a second chip including a second functional face and a second back face that are opposite to each other, wherein second external connection terminals are arranged on the functional face, and the second chip is flip-mounted on the first molding layer, wherein the second external connection terminals on the second chip are electrically connected to the top surfaces of the plurality of first external connection terminals and the plurality of protruded metal pillars; and
a second molding layer configured to mold the second chip on the first molding layer.

### BRIEF DESCRIPTION OF THE DRAWINGS

FIG. 1 is a schematic structural diagram of a carrier plate provided in a process for forming a package structure according to some embodiments of the present disclosure;

FIG. 2 is a schematic structural diagram of a plurality of protruded metal pillars and a metal layer formed on an upper surface of the carrier plate in the process for forming the package structure according to some embodiments of the present disclosure;

FIG. 3 is a schematic structural diagram of a first chip provided in the process for forming the package structure according to some embodiments of the present disclosure;

FIG. 4 is a schematic structural diagram of a first molding layer configured to mold the first chip and the metal pillars formed in the process for forming the package structure according to some embodiments of the present disclosure;

FIG. 5 is a schematic structural diagram of a second chip provided in the process for forming the package structure according to some embodiments of the present disclosure;

FIG. 6 is a schematic structural diagram of an underfill layer filled in a space between the second chip and the first molding layer formed in the process for forming the package structure according to some embodiments of the present disclosure;

FIG. 7 is a schematic structural diagram of a second molding layer configured to mold the second chip formed on the first molding layer in the process for forming the package structure according to some embodiments of the present disclosure;

FIG. 8 is a schematic structural diagram of the carrier plate and the first bonding layer removed in the process for forming the package structure according to some embodiments of the present disclosure;

FIG. 9 is a schematic structural diagram of external connection bumps connected to the metal pillars formed on bottom surfaces of the metal pillars in the process for forming the package structure according to some embodiments of the present disclosure;

FIG. 10 is a schematic structural diagram of a carrier plate provided in the process for forming the package structure according to some embodiments of the present disclosure;

FIG. 11 is a schematic structural diagram of a first chip provided in the process for forming the package structure according to some embodiments of the present disclosure;

FIG. 12 is a schematic structural diagram of a first molding layer configured to mold the first chip and the metal pillars formed in the process for forming the package structure according to some embodiments of the present disclosure;

FIG. 13 is a schematic structural diagram of a second chip provided in the process for forming the package structure according to some embodiments of the present disclosure;

FIG. 14 is a schematic structural diagram of the carrier plate and the first bonding layer removed in the process for forming the package structure according to some embodiments of the present disclosure;

FIG. 15 is a schematic structural diagram of external connection bumps connected to the metal pillars formed on the bottom surfaces of the metal pillars in the process for forming the package structure according to some embodiments of the present disclosure;

FIG. 16 is a schematic structural diagram of a carrier plate provided in a process for forming a package structure according to some embodiments of the present disclosure;

FIG. 17 is a schematic structural diagram of a first chip provided in the process for forming the package structure according to some embodiments of the present disclosure;

FIG. 18 is a schematic structural diagram of a first molding layer configured to mold the first chip and the metal pillars formed in the process for forming the package structure according to some embodiments of the present disclosure;

FIG. 19 is a schematic structural diagram of a second chip provided in the process for forming the package structure according to some embodiments of the present disclosure; and

FIG. 20 is a schematic structural diagram of the carrier plate and the first bonding layer removed in the process for forming the package structure according to some embodiments of the present disclosure.

### DETAILED DESCRIPTION

The specific embodiments of the present disclosure are described in detail hereinafter with reference to the accompanying drawings. In the description of the embodiments of the present disclosure, for ease of illustration, the schematic structural views are not partially enlarged according to a typical scale, and the schematic views are given for exemplary purpose only, which do not limit the protection scope of the present disclosure. In addition, in practice, a three-dimension spatial size in terms of length, width, and depth needs to be included.

Some embodiments of the present disclosure provide a method for forming a package structure. Hereinafter, the method is described with reference to the accompanying drawings.

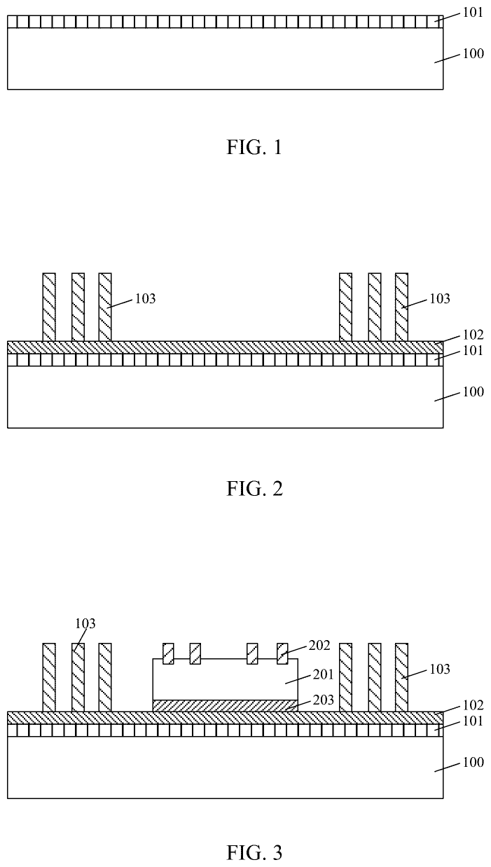

Referring to FIG. 1, a carrier plate 100 is provided.

The carrier plate 100 acts as a carrier for subsequent processes, and the carrier plate 100 may be removed in subsequent processes.

In some embodiments, the carrier plate 100 may be a glass carrier plate, a ceramic carrier plate, a resin carrier plate, or a silicon carrier plate. In this embodiment, the carrier plate 100 is a glass carrier plate.

In some embodiments, a temporary bonding layer 101 is further formed on a surface (upper surface) of the carrier plate 100. The temporary bonding layer 101 is configured to improve an adhesion strength between a metal layer 102 (referring to FIG. 2) subsequently formed on the carrier plate 100 and the carrier plate 100. In some embodiments, the temporary bonding layer 101 is made of a polymer material, and may be removed by heating or UV irradiation, to separate the carrier plate.

Referring to FIG. 2, a plurality of protruded metal bumps 103 and a metal layer 102 are formed on the surface of the carrier plate 100, and the metal layer serves as a first bonding layer of the metal layer 102.

The metal layer 102, as the first bonding layer, is configured to be subsequently bonded to a second bonding layer on a back face of a first chip. In addition, the metal layer 102 may also serve as a conductive layer in forming the metal pillars 102 by an electroplating process.

In some embodiments, the metal layer 102 is made of one or more of aluminum, nickel, tin, tungsten, platinum, copper, titanium, chromium, tantalum, gold, or silver. The metal layer 102 is formed by sputtering.

In some embodiments, the metal layer 102 is formed on a surface of the temporary bonding layer 101 on the carrier plate 100.

Metal bumps 103 are protruded from a surface of the metal layer 102. The metal bumps 103 are configured to be subsequently electrically connected to a second chip flip-mounted, to lead an electrical contact point on the second chip to a surface, away from the second chip, of the first molding layer. In some embodiments, a plurality (at least two) of metal pillars 103 are arranged.

In some embodiments, the metal pillars 103 are made of aluminum, nickel, tungsten, platinum, copper, titanium, chromium, tantalum, tin alloy, gold, or silver. The metal pillars 103 may be formed by, for example, an electroplating process. In forming the metal pillars 103 by the electroplating process, the metal layer 102 serves as a conductive layer for electroplating.

The electroplating process is a process of reducing metal ions to metal atoms through reaction under the effect of an external electrical field, and depositing metal on a cathode. During electroplating, an electroplating metal serves as an anode, and a to-be-electroplated piece serves as a cathode. In a specific embodiment, the process for forming the metal pillars 103 by the electroplating process includes: forming a mask layer (not illustrated in the drawings) on the metal layer 103, wherein a plurality of openings exposing a portion of the surface of the metal layer 103 are defined in the mask layer; an electroplating solution is received in a plating tank, wherein the electroplating solution is composed of aqueous solution containing a compound of plating metal, a conductive salt, a buffers, a pH adjuster, and an additive; at least partially placing the carrier plate 100 with the mask layer into the plating tank, and using the metal layer 102 as a cathode, using the plated metal as an anode, connecting the metal layer 102 on the carrier plate 100 to a negative terminal of a direct-current power source, and connecting the plating metal to a positive terminal of the direct-current power source, wherein upon power on, metal ions in the electroplating solution move he surface of the metal layer 102 exposed by the openings in the mask layer under the effect of a potential difference and are reduced to the metal pillars 103, and the metal of the anode (the plating metal) is oxidized to metal ions which enter the electroplating solution to maintain a concentration of metal ions to be plated; and removing the mask layer upon formation of the metal pillars 103.

In some embodiments, the metal layer 102 may include a middle region and an edge region surrounding the middle region, and the formed metal pillars 103 are distributed on the edge region of the metal layer 102. The middle region of the metal layer 102 is configured to accommodate the first chip and to be bonded to the first back face of the first chip.

Referring to FIG. 3, a second chip 201 is provided, wherein the first chip 201 includes a first functional face and a first back face that are opposite to each other, a plurality of first external connection terminals 203 are arranged on the first functional face, and a second bonding layer 204 is arranged on the first back face; and the second bonding layer 204 on the first back face of the first chip 201 is bonded to the first bonding layer (the metal layer 102) on the upper surface of the carrier plate 100.

In some embodiments, the first chip 201 is a chip having a high-density interconnect structure, which serves as an interconnect bridge for interconnection between other chips that are subsequently flip-mounted (a plurality of second chips that are subsequently flip-mounted).

The first chip 201 includes a first functional face and a back face that are opposite to each other. The interconnect structure is disposed on the first chip 201, and the first external connection terminals 203 are electrically connected to the interconnect structure. In some embodiments, the first external connection terminals 203 are first pads on the first functional face of the first chip 201 (a surface of the first pad may be flush with the first functional face). In some other embodiments, the first external connection terminals 203 include first pads on the first functional face of the first chip 201 and first solder bumps on the first pad, protruded from the surface, on the first functional face. In some embodiments, the first solder bumps are solder balls, or include metal bumps and solder balls on top surfaces of the metal bumps. In some embodiments, the first pads are made of one or more of aluminum, nickel, tin, tungsten, platinum, copper, titanium, chromium, tantalum, gold, or silver. In some embodiments, the metal bumps are made of one or more of aluminum, nickel, tin, tungsten, platinum, copper, titanium, chromium, tantalum, gold, or silver. The solder balls are made of one or more of tin, tin-silver, tin-lead, tin-silver-copper, tin-silver-zinc, tin-zinc, tin-bismuth-indium, tin-indium, tin-gold, tin-copper, tin-zinc-indium, or tin-silver-antimony.

The second bonding layer 204 on the first back face of the first chip 201 is bonded to the first bonding layer (the metal layer 102) on the upper surface of the carrier plate 100, such that the first chip 201 and the carrier plate 100 are secured to each other reliably, and hence the first chip 201 is securely fixed to the carrier plate 100. In this way, the first chip 201 is prevented from shifting or moving (leftward and rightward movements or upward and downward movements) during the subsequent packaging process (for example, during formation of the first molding layer and flip-mounting of the second chip). This ensures positional accuracy of the first chip 201 during the packaging process, thereby improving precision of electrical connection between the first chip 201 and the subsequent second chip and enhancing electrical performance of the package structure.

The second bonding layer 204 on the first back face of the first chip 201 to the first bonding layer (the metal layer 102) on the upper surface of the carrier plate 100 by a bonding process.

The second bonding layer 204 may be made of a metal or a dielectric material.

In some embodiments, in the case that the second bonding layer 204 is made of a metal, the second bonding layer 204 and the metal layer 102 are made of the same material, and the first back face of the first chip 201 is bonded to the metal layer 102 by metal-metal diffusion bonding. In some embodiments, the second bonding layer 204 may be made of one or more of aluminum, nickel, tin, tungsten, platinum, copper, titanium, chromium, tantalum, gold, or silver.

In some embodiments, in the case that the second bonding layer 204 is made of a dielectric material, the dielectric material may be silicon oxide, and the first back face of the first chip 201 is bonded to the metal layer 102 by metal-metal diffusion bonding.

In some embodiments, after the first back face of the first chip 201 is bonded to the first bonding layer (the metal layer 102) on the upper surface of the carrier plate 100, top surfaces of the first external connection terminals 204 on the first functional face of the first chip 201 are flush with top surfaces of the metal pillars 103.

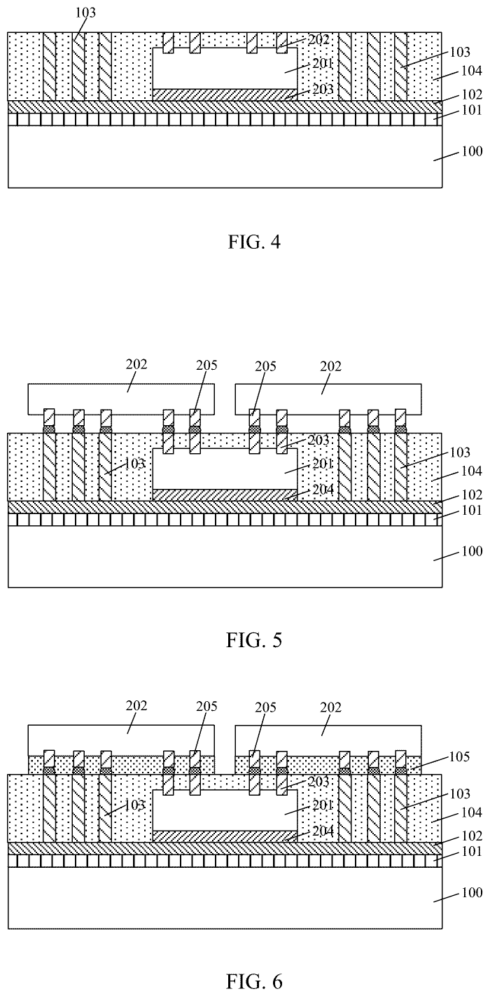

Referring to FIG. 4, a first molding layer 104 configured to mold the first chip 201 and the metal pillars 103 is formed. The first molding layer 104 exposes the top surfaces of the first external connection terminals 203 and the metal pillars 103.

In some embodiments, the first molding layer 104 is made of molding resin, including epoxy resin, polyimide resin, benzocyclobutene resin, or polybenzoxazole resin. In some embodiments, the first molding layer 104 is formed by an injection molding or transfer molding process.

The formed first molding layer 104 wraps a side wall of the first chip 201, sidewall surfaces of the first external connection terminals 203, and sidewall surfaces of the metal pillars 103, and exposes the top surfaces of the first external connection terminals 203 and the metal pillars 103.

Referring to FIG. 5, a second chip 202 is provided. The second chip 202 includes a second functional face and a second back face that are opposite to each other. Second external connection terminals 205 are arranged on the functional face. The second chip 202 is flip-mounted on the first molding layer 104. The second external connection terminals 205 on the second chip 202 are electrically connected to the top surfaces of the first external connection terminals 203 and the metal pillars 103.

A plurality of second chips 202 are provided. The plurality of second chips 202 are flip-mounted on the first molding layer 104. For each of the second chips 202, a portion of the second external connection terminals 205 are electrically connected to the first external connection terminals 203 on the first chip 201, and another portion of the second external connection terminals 205 are electrically connected to the metal pillars 103. In this way, the second chips 202 are interconnected via the first chip 201 buried in the first molding layer 104, and via the metal pillars 103 in the first molding layer 104, a portion of the electrical connection points (the second external connection terminals 205) on the second chip 202 are led to a back face of the first molding layer 104 (the back face of the first molding layer 104 is a surface, far away from the second chip 202, of the first molding layer 104) to facilitate connection to other chips or devices.

The second chip 202 includes a second functional face and a second back face that are opposite to each other. A plurality of second external connection terminals 205 are arranged on the second functional face. In some embodiments, the second external connection terminals 205 include second pads on the second functional face of the second chip 202 and second solder bumps on the second pad, protruded from the surface, on the second functional face. In some embodiments, the second solder bumps include metal bumps and solder balls on top surfaces of the metal bumps. In some embodiments, the second pads are made of one or more of aluminum, nickel, tin, tungsten, platinum, copper, titanium, chromium, tantalum, gold, or silver. In some embodiments, the metal bumps are made of one or more of aluminum, nickel, tin, tungsten, platinum, copper, titanium, chromium, tantalum, gold, or silver. The solder balls are made of one or more of tin, tin-silver, tin-lead, tin-silver-copper, tin-silver-zinc, tin-zinc, tin-bismuth-indium, tin-indium, tin-gold, tin-copper, tin-zinc-indium, or tin-silver-antimony.

The plurality of second chips 202 may have the same function or different functions. The plurality of second chips 202 may include logic chips and/or storage chips. In some embodiments, the logic chip includes a gate array, a cell-based array, an embedded array, an application-specific integrated circuit (ASIC), a field-programmable gate array (FPGA), a complex programmable logic device (CPLD), a central processing unit (CPU), a microprocessor units (MPU), a microcontroller unit (MCU), an integrated circuit (IC), an application processor (AP), a display driver IC (DDI), a radio frequency (RF) chip, a power management IC, or a complementary metal-oxide-semiconductor (CMOS) image sensor. In some embodiments, the memory chip includes a volatile memory chip, such as a dynamic random access memory (DRAM) or a static RAM (SRAM), or a non-volatile memory chip, such as a flash memory (Flash), a phase change RAM (PRAM), a magnetoresistive RAM (MRAM), a ferroelectric RAM (FeRAM) or a resistive RAM (ReRAM).

In some embodiments, prior to flip-mounting the second chip 202 on the first molding layer 104, the method further includes: forming a redistribution layer (not illustrated in the drawings) on the first molding layer 104, wherein the redistribution layer is electrically connected to the first external connection terminals 203 and the metal pillars 103; and flip-mounting the second chip 202 on the first molding layer 104, wherein the second external connection terminals 205 on the second chip 202 are electrically connected to the first external connection terminals 203 and the metal pillars 103 via the redistribution layer.

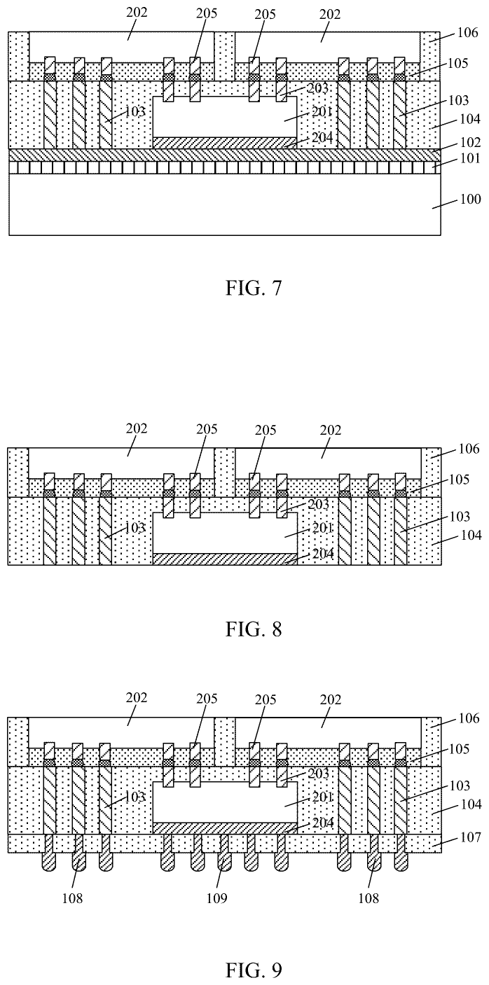

Referring to FIG. 6 and FIG. 7, a second molding layer 106 configured to mold the second chip 202 is formed on the first molding layer 104.

In some embodiments, prior to forming the second molding layer 106, an underfill layer 105 (referring to FIG. 6) is filled in a space between the second chip 202 and the first molding layer 104. The underfill layer 105 achieves a function of protecting connection solder points between the second chip 202 and the first molding layer 104, such that the second chip 202 is protected from impacts caused by moistures, ion contaminants, radiation, and harmful operating environments such as mechanical stretching, shearing, twisting, and vibration. In addition, the underfill layer 105 further reduces mismatch of thermal expansion coefficient between the second chip 202 and the first molding layer 104, and thus improves reliability of the package structure. In some embodiments, the underfill layer 105 is made of a silicon-based resin material, a thermoplastic resin material, a heat-cured resin material, or an ultraviolet-cured resin material, and a process for forming the underfill layer includes a glue dispensing process.

In some embodiments, the second molding layer 106 is made of molding resin, including epoxy resin, polyimide resin, benzocyclobutene resin, or polybenzoxazole resin. In some embodiments, the second molding layer 106 is formed by an injection molding or transfer molding process. The formed second molding layer 106 wraps a sidewall surface of the second chip, and exposes a surface of the second back face of the second chip 202. In this way, a heat sink may be mounted on the second back face of the second chip 202 to dissipate heat of the second chip, such that the second chip 202 may be controlled to a suitable temperature range. In some embodiments, the heat sink is made of a material with high thermal conductivity. The material with high thermal conductivity includes a metal (for example, copper, aluminum, gold, nickel, steel, or stainless steel) or a carbon-containing material (for example, graphite, graphene, or carbon nanotube).

Referring to FIG. 8, the carrier plate 100 and the first bonding layer (the metal layer 102, referring to FIG. 7) to expose the bottom surfaces of the metal pillars 103 and the surface of the second bonding layer 204 on the first back face of the first chip 201.

The carrier plate 100 may be removed by a delamination process, and the removed carrier plate 100 may be reused. After the carrier plate 100 is removed, the first bonding layer (the metal layer 102) is removed. The metal layer 102 may be removed by an etching process or a chemical mechanical polishing (CMP) process.

After the carrier plate 100 and the metal layer 102 are removed, in addition to the bottom surfaces of the metal pillars 103, a bottom surface of the second bonding layer 204 on the first back face of the first chip 201 and a bottom surface of the first molding layer 104 are also exposed.

In some embodiments, in the case that a temporary bonding layer 101 is further formed between the first bonding layer (the metal layer 102) and the carrier plate 100, the temporary bonding layer 101 is removed while removing the carrier plate 100 and the first bonding layer (the metal layer 102).

Referring to FIG. 9, external connection bumps 108 connected to the metal pillars 103 are formed on the bottom surfaces of the metal pillars 103.

The external connection bumps 108 are configured to connect the package structure according to the present disclosure to other chips or devices (for example, a package substrate or a PCB substrate).

In some embodiments, a metal layer is arranged on the upper surface of the carrier plate, wherein the metal layer is used as the first bonding layer, and the protruded metal pillars are formed on an upper surface of the metal layer.

In some embodiments, the second bonding layer is made of a metal or a dielectric material.

In some embodiments, in the case that the second bonding layer is made of a metal, the second bonding layer and the metal layer are made of the same material.

In some embodiments, a metal layer, metal pillars protruded from an upper surface of the metal layer, and a photosensitive polymer layer on the upper surface of the metal layer and wrapping lower side walls of the metal pillars are arranged on the upper surface of the carrier plate, wherein the photosensitive polymer layer is used as the first bonding layer.

In some embodiments, a temporary bonding layer is further formed between the metal layer and the carrier plate, wherein the temporary bonding layer is removed while removing the carrier plate and the first bonding layer.

In some embodiments, a temporary bonding layer and metal pillars protruded from an upper surface of the temporary bonding layer are arranged on the upper surface of the carrier plate, wherein the temporary bonding layer is used as the first bonding layer.

In some embodiments, the temporary bonding layer is made of silicon oxide.

In some embodiments, the second bonding layer is made of a metal.

In some embodiments, the method further includes: forming pseudo-external connection bumps on the second bonding layer on the first back face of the first chip.

In some embodiments, the pseudo-external connection bumps are formed on a surface of the second bonding layer on the first back face of the first chip while forming the external connection bumps connected to the metal pillars on the bottom surfaces of the metal pillars.

In some embodiments, prior to forming the external connection bumps and the pseudo-external connection bumps, the method further includes: forming a polymer layer on the back face of the first molding layer, wherein a first opening exposing the surface of the second bonding layer on the first back face of the first chip and a second opening exposing the bottom surfaces of the metal pillars are defined in the polymer layer; wherein the pseudo-external connection bumps are formed in the first opening, the external connection bumps are formed in the second opening, and the pseudo-external connection bumps and the external connection bumps all protrude from a surface of the polymer layer.

In some embodiments, prior to flip-mounting the second chip on the first molding layer, the method further includes: forming a redistribution layer on the first molding layer, wherein the redistribution layer is electrically connected to the first external connection terminals and the metal pillars; and flip-mounting the second chip on the first molding layer, wherein the second external connection terminals on the second chip are electrically connected to the first external connection terminals and the metal pillars via the redistribution layer.

In some embodiments, the method further includes: forming pseudo-external connection bumps 109 on the surface of the second bonding layer 204 on the first back face of the first chip 201. The pseudo-external connection bumps 109 may be formed simultaneously with the external connection bumps 108. That is, the pseudo-external connection bumps 109 are formed on the first back face of the first chip 201 while forming the external connection bumps 108 connected to the metal pillars 103 on the bottom surfaces of the metal pillars 103.

In some embodiments, the process for forming the external connection bumps 108 and the pseudo-external connection bumps 109 includes: forming a polymer layer 107 on a surface of the back face of the first molding layer, wherein a first opening exposing a surface of the second bonding layer 204 on the first back face of the first chip 201 the polymer layer 107 and a second opening exposing the bottom surfaces of the metal pillars 103 are defined in the polymer layer, and the polymer material 107 is made of resin, including photosensitive resin; an under-bump metallization (UBM, not illustrated in the drawings) is formed on innerwall surfaces of the first opening and the second opening and a surface of the polymer layer 107; forming a (second) mask layer on the polymer layer 107, wherein a plurality of third openings are defined in the (second) mask layer, the third openings are in communication with the corresponding first opening and second opening, and a size of the third opening is greater than a size of the first opening and a size of the second openings; forming the pseudo-external connection bumps in the first opening and the corresponding third opening, and forming the external connection bumps in the second opening and the corresponding third opening, wherein the external connection bumps 108 and the pseudo-external connection bumps 109 may be formed by an electroplating process; and removing the (second) mask layer and the UBM on both sides of the external connection bumps 108 and the pseudo-external connection bumps 109, such that the external connection bumps 108 and the pseudo-external connection bumps 109 all protrude from a surface of the polymer layer 107. By forming the pseudo-external connection bumps 109, in one aspect, the formed pseudo-external connection bumps 109 serves as a mechanical structural balance to increase reliability, and during formation of the pseudo-external connection bumps 109, an opening needs to be defined in the polymer layer 107 at the bottom of the first chip 201 (to form the second opening), which prevents positional shifts of the external connection bumps 108 caused by an internal stress; and in another aspect, in the case that the pseudo-external connection bumps 109 are in contact with the second bonding layer 204 of a metal material on the back surface of the first chip 201, the pseudo-external connection bumps 109 may be grounded to improve the electromagnetic interference (EMI) shielding effect.

In some embodiments, both the external connection bumps 108 and the pseudo-external connection bumps 109 include metal bumps and solder balls on top surfaces of the metal bumps. In some embodiments, the metal bumps may be made of one or more of aluminum, nickel, tin, tungsten, platinum, copper, titanium, chromium, tantalum, gold, or silver. The solder balls are made of one or more of tin, tin-silver, tin-lead, tin-silver-copper, tin-silver-zinc, tin-zinc, tin-bismuth-indium, tin-indium, tin-gold, tin-copper, tin-zinc-indium, or tin-silver-antimony.

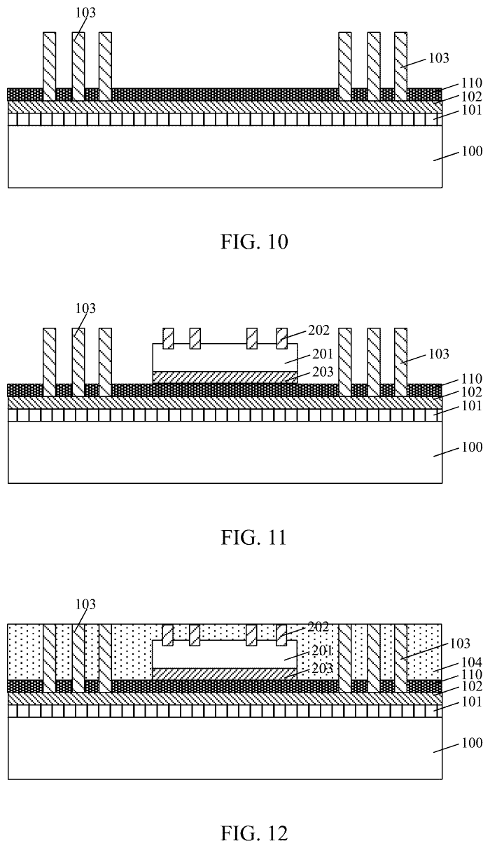

Some other embodiments of the present disclosure further provide a method for forming a package structure. Different from the above embodiments, in this embodiment, the first bonding layer is different (it should be noted that in this embodiment, portions the same as or similar to those in the above embodiments are not described any further, which may be referenced to the corresponding portions described in the above embodiments) First, referring to FIG. 10, a metal layer 102, metal pillars 103 protruded from an upper surface of the metal layer 102, and a photosensitive polymer layer 110 on the upper surface of the metal layer 102 and wrapping lower side walls of the metal pillars 103 are arranged on the upper surface of the carrier plate 100, wherein the photosensitive polymer layer 110 is used as the first bonding layer.

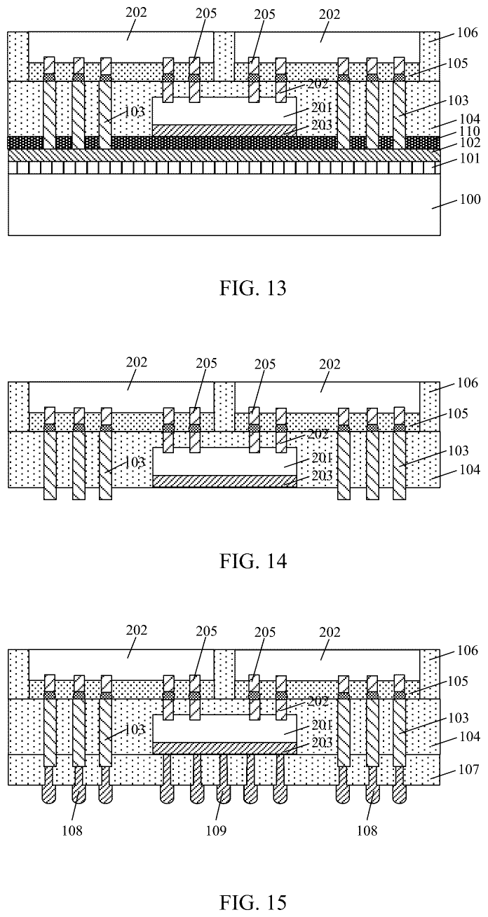

In one aspect, the photosenstive polymer layer 110, as the first bonding layer, is bonded to the subsequent second bonding layer 204 on the first back face of the first chip 201, such that the first chip 201 is securely fixed to the carrier plate 100. In this way, the first chip 201 is prevented from shifting or moving (leftward and rightward movements or upward and downward movements) during the subsequent packaging process (for example, during formation of the first molding layer and flip-mounting of the second chip). This ensures positional accuracy of the first chip 201 during the packaging process, thereby improving precision of electrical connection between the first chip 201 and the subsequent second chip and enhancing electrical performance of the package structure. In another aspect, the photosensitive polymer layer 110 is capable of better securing the metal pillars 103. In this way, the metal pillars 103 are prevented from shifting or moving (leftward and rightward movements or upward and downward movements) during subsequent formation of the first molding layer 104 (referring to FIG. 12). This ensures positional accuracy of the metal pillars 103 during the packaging process, thereby improving precision of electrical connection between the metal pillars 103 and the subsequent second chip 202 (referring to FIG. 13) and further enhancing electrical performance of the package structure.

In some embodiments, the photosensitive polymer layer 110 is made of photosensitive epoxy resin, photosensitive polyimide resin, photosensitive benzocyclobutene resin, or photosensitive polybenzoxazole resin.

In some embodiments, during formation of the metal pillars 103 by the electroplating process, the mask layer is made of a photosensitive polymer material; and after the metal pillars 103 are formed in the openings of the mask layer by the electroplating process, the photosensitive polymer material is etched back to remove a portion of the photosensitive polymer by a specific thickness, and the remaining photosensitive polymer material is used as the photosensitive polymer layer 110.

In some embodiments, a temporary bonding layer 101 is further formed between the metal layer 102 and the upper surface of the carrier plate 100.

Referring to FIG. 11, a second chip 201 is provided, wherein the first chip 201 includes a first functional face and a first back face that are opposite to each other, a plurality of first external connection terminals 203 are arranged on the first functional face, and a second bonding layer 204 is arranged on the first back face; and the second bonding layer 204 on the first back face of the first chip 201 is bonded to the first bonding layer (the photosensitive polymer layer 110) on the upper surface of the carrier plate 100.

Referring to FIG. 12, a first molding layer 104 configured to mold the first chip 201 and the metal pillars 103 is formed. The first molding layer 104 exposes the top surfaces of the first external connection terminals 203 and the metal pillars 103.

Referring to FIG. 13, a second chip 202 is provided, wherein the second chip 202 includes a second functional face and a second back face that are opposite to each other, and second external connection terminals 205 are arranged on the functional face; the second chip 202 is flip-mounted on the first molding layer 104, wherein the second external connection terminals 205 on the second chip 202 are electrically connected to the top surfaces of the first external connection terminals 203 and the metal pillars 103; and a second molding layer 106 configured to mold the second chip 202 is formed on the first molding layer 104.

Referring to FIG. 14, the carrier plate 100 and the first bonding layer (the photosensitive polymer layer 110, referring to FIG. 13) to expose the bottom surfaces of the metal pillars 103 and the surface of the second bonding layer 204 on the first back face of the first chip 201.

After the first bonding layer (the photosensitive polymer layer 110) is removed, in addition to the bottom surfaces of the metal pillars 103, a portion of sidewall surfaces of the metal pillars 103 are exposed.

Referring to FIG. 15, external connection bumps 108 connected to the metal pillars 103 are formed the bottom surfaces of the metal pillars 103; and pseudo-external connection bumps 109 are formed on a surface of the second bonding layer 204 on the first back face of the first chip 201.

A portion of both the external connection bumps 108 and the pseudo-external connection bumps 109 are disposed in the polymer layer 107 on a back surface of the first molding layer 104.

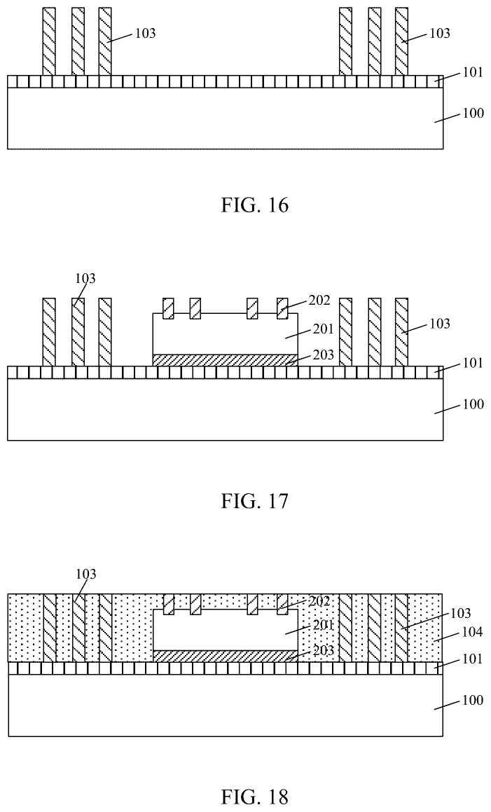

Some other embodiments of the present disclosure further provide a method for forming a package structure. Different from the above embodiments, in this embodiment, the first bonding layer is different (it should be noted that in this embodiment, portions the same as or similar to those in the above embodiments are not described any further, which may be referenced to the corresponding portions described in the above embodiments) First, referring to FIG. 16, a temporary bonding layer 101 and metal pillars 103 protruded from an upper surface of the temporary bonding layer 101 are arranged on the upper surface of the carrier plate 100, wherein the temporary bonding layer 101 is used as the first bonding layer.

The temporary bonding layer 101, as the first bonding layer, is bonded to the subsequent second bonding layer 204 on the first back face of the first chip 201, such that the first chip 201 is securely fixed to the carrier plate 100. In this way, the first chip 201 is prevented from shifting or moving (leftward and rightward movements or upward and downward movements) during the subsequent packaging process (for example, during formation of the first molding layer and flip-mounting of the second chip). This ensures positional accuracy of the first chip 201 during the packaging process, thereby improving precision of electrical connection between the first chip 201 and the subsequent second chip and enhancing electrical performance of the package structure.

In some embodiments, the temporary bonding layer 101 is made of silicon oxide.

Referring to FIG. 17, a second chip 201 is provided, wherein the first chip 201 includes a first functional face and a first back face that are opposite to each other, and a plurality of first external connection terminals 203 are arranged on the first functional face, and a second bonding layer 204 is arranged on the first back face; and the second bonding layer 204 on the first back face of the first chip 201 is bonded to the first bonding layer (the temporary bonding layer 101) on the upper surface of the carrier plate 100.

Referring to FIG. 18, a first molding layer 104 configured to mold the first chip 201 and the metal pillars 103 is formed. The first molding layer 104 exposes the top surfaces of the first external connection terminals 203 and the metal pillars 103.

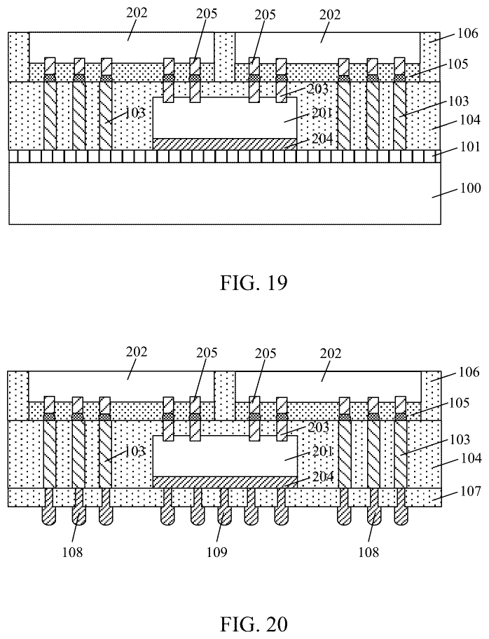

Referring to FIG. 19, a second chip 202 is provided, wherein the second chip 202 includes a second functional face and a second back face that are opposite to each other, and second external connection terminals 205 are arranged on the functional face; the second chip 202 is flip-mounted on the first molding layer 104, wherein the second external connection terminals 205 on the second chip 202 are electrically connected to the top surfaces of the first external connection terminals 203 and the metal pillars 103; and a second molding layer 106 configured to mold the second chip 202 is formed on the first molding layer 104.

Referring to FIG. 20, the carrier plate 100 and the first bonding layer (the temporary bonding layer 101, referring to FIG. 19) to expose the bottom surfaces of the metal pillars 103 and the surface of the second bonding layer 204 on the first back face of the first chip 201; the external connection bumps 108 connected to the metal pillars 103 are formed on the bottom surfaces of the metal pillars 103; and the pseudo-external connection bumps 109 are formed on the surface of the second bonding layer 204 on the first back face of the first chip 201.

A portion of both the external connection bumps 108 and the pseudo-external connection bumps 109 are disposed in the polymer layer 107 on a back surface of the first molding layer 104.

Some embodiments of the present disclosure provide a package structure. Referring to FIG. 7, the package structure includes:
a carrier plate 100;
a first bonding layer (metal layer 102) and a plurality of protruded metal pillars 103 on an upper surface of the carrier plate 100;
a first chip 201 including a first functional face and a first back face that are opposite to each other, wherein a plurality of first external connection terminals 203 are arranged on the first functional face, and a second bonding layer 204 is arranged on the first back face, wherein the second bonding layer 204 on the first back face of the first chip 201 is bonded to the first bonding layer (the metal layer 102) on the upper surface of the carrier plate 100;
a first molding layer 104 configured to mold the first chip 201 and the metal pillars 103 is formed, wherein the first molding layer 104 exposes top surfaces of the first external connection terminals 203 and the metal pillars 103;
a second chip 202 including a second functional face and a second back face that are opposite to each other, wherein second external connection terminals 205 are arranged on the functional face, and the second chip 202 is flip-mounted on the first molding layer 104, wherein the second external connection terminals 205 on the second chip 202 are electrically connected to the first external connection terminals 203 and the metal pillars 103; and
a second molding layer 106 configured to mold the second chip 202 on the first molding layer 104.

In the embodiments, a metal layer 102 is arranged on the upper surface of the carrier plate 100, wherein the metal layer 102 is used as the first bonding layer, and the protruded metal pillars 103 are formed on an upper surface of the metal layer 102.

In some embodiments, a metal layer is arranged on the upper surface of the carrier plate, wherein the metal layer is used as the first bonding layer, and the protruded metal pillars are formed on an upper surface of the metal layer.

In some embodiments, the second bonding layer is made of a metal or a dielectric material; and in the case that the second bonding layer is made of a metal, the second bonding layer and the metal layer are made of the same material.

In some embodiments, a metal layer, metal pillars protruded from an upper surface of the metal layer, and a photosensitive polymer layer on the upper surface of the metal layer and wrapping lower side walls of the metal pillars are arranged on the upper surface of the carrier plate, wherein the photosensitive polymer layer is used as the first bonding layer.

In some embodiments, a temporary bonding layer is formed between the metal layer and the carrier plate.

In some embodiments, a temporary bonding layer and metal pillars protruded from an upper surface of the temporary bonding layer are arranged on the upper surface of the carrier plate, wherein the temporary bonding layer is used as the first bonding layer.

In some embodiments, the temporary bonding layer is made of silicon oxide.

In some embodiments, the second bonding layer is made of a metal.

In some embodiments, the second bonding layer 204 is made of a metal or a dielectric material; and in the case that the second bonding layer 204 is made of a metal, the second bonding layer 204 and the first bonding layer (the metal layer 102) are made of the same material.

In some embodiments, referring to FIG. 13, a metal layer 102, metal pillars 103 protruded from an upper surface of the metal layer 102, and a photosensitive polymer layer 110 on the upper surface of the metal layer 102 and wrapping lower side walls of the metal pillars 103 are arranged on the upper surface of the carrier plate 100, wherein the photosensitive polymer layer 110 is used as the first bonding layer.

In some embodiments, referring to FIG. 7 or FIG. 13, a temporary bonding layer 101 is further formed between the metal layer 102 and the carrier plate 100.

In some embodiments, referring to FIG. 19, a temporary bonding layer 101 and metal pillars 103 protruded from an upper surface of the temporary bonding layer 101 are arranged on the upper surface of the carrier plate 100, wherein the temporary bonding layer 101 is used as the first bonding layer.

In some embodiments, the temporary bonding layer 101 is made of silicon oxide, and the second bonding layer 204 is made of a metal.

In summary, a package structure and a method for forming the same are disclosed. In the method for forming the package structure: a first bonding layer and a plurality of protruded metal pillars are formed on an upper surface of a carrier plate; a first chip including a first functional face and a first back face that are opposite to each other is provided, wherein a plurality of first external connection terminals are arranged on the first functional face, and a second bonding layer is arranged on the first back face; the second bonding layer on the first back face of the first chip is bonded to the first bonding layer on the upper surface of the carrier plate; a first molding layer configured to mold the first chip and the metal pillars is formed, wherein the first molding layer exposes top surfaces of the first external connection terminals and the metal pillars; a second chip including a second functional face and a second back face that are opposite to each other is provided, wherein a plurality of second external connection terminals are arranged on the second functional face; the second chip is flip-mounted on the first molding layer, wherein the second external connection terminals on the second chip are electrically connected to the top surfaces of the first external connection terminals and the metal pillars; a second molding layer configured to mold the second chip on the first molding layer is formed; the carrier plate and the first bonding layer are removed to expose bottom surfaces of the metal pillars and a surface of the second bonding layer on the first back face of the first chip; and external connection bumps connected to the metal pillars are formed on the bottom surfaces of the metal pillars. During the packaging process according to the present disclosure, the second bonding layer on the first back face of the first chip is bonded to the first bonding layer on the upper surface of the carrier plate, such that the first chip and the carrier plate are secured to each other reliably, and hence the first chip is securely fixed to the carrier plate. In this way, the first chip is prevented from shifting or moving (leftward and rightward movements or upward and downward movements) during the subsequent packaging process (for example, during formation of the first molding layer and flip-mounting of the second chip). This ensures positional accuracy of the first chip during the packaging process, thereby improving precision of electrical connection between the first chip and the subsequent second chip and enhancing electrical performance of the package structure.

In addition, terms “comprise,” “include,” and variations thereof used herein in the text of the present disclosure are intended to define a non-exclusive meaning. It should be noted that the terms such as “first,” “second,” and the like in the specifications, claims and the accompanying drawings of the present disclosure are intended to distinguish different objects but are not intended to define a specific order or a definite time sequence. Unless otherwise clearly indicated in the context, it should be understood that the data used in this way can be interchanged under appropriate circumstances. In cases of no conflict, the embodiments and features in the embodiments of the present disclosure may be combined together. Further, in the above description, descriptions of well-known components and techniques are omitted so as not to unnecessarily obscure the inventive concepts of the present disclosure. In various embodiments of the present disclosure, the same or similar parts between the embodiments may be referenced to each other. In each embodiment, the portion that is different from other embodiments is concentrated and described.

Although the present disclosure has been disclosed above with reference to preferred embodiments, these embodiments are not intended to limit the present disclosure but illustrate the present disclosure. Without departing from the spirit and scope of the present disclosure, any person skilled in the art may make possible variations and modifications to the technical solutions based on the method and technical content disclosed herein in this literature. Therefore, any content without departing from the technical solutions of the present disclosure and any simple variation, equivalent replacement and modification made based on the technical essence of the present disclosure shall fall within the protection scope defined by the technical solutions of the present disclosure.

What is claimed is:

1. A method for forming a package structure, comprising:
providing a carrier plate;
forming a first bonding layer and a plurality of protruded metal pillars on an upper surface of the carrier plate;
providing a first chip comprising a first functional face and a first back face that are opposite to each other, wherein a plurality of first external connection terminals are arranged on the first functional face, and a second bonding layer is arranged on the first back face;
bonding the second bonding layer on the first back face of the first chip to the first bonding layer on the upper surface of the carrier plate;
forming a first molding layer configured to mold the first chip and the plurality of protruded metal pillars, wherein the first molding layer exposes top surfaces of the plurality of first external connection terminals and the plurality of protruded metal pillars;
providing a second chip comprising a second functional face and a second back face that are opposite to each other, wherein a plurality of second external connection terminals are arranged on the second functional face;
flip-mounting the second chip on the first molding layer, wherein the plurality of second external connection terminals on the second chip are electrically connected to the top surfaces of the plurality of first external connection terminals and the plurality of protruded metal pillars;
forming a second molding layer configured to mold the second chip on the first molding layer;
removing the carrier plate and the first bonding layer to expose bottom surfaces of the plurality of protruded metal pillars and a surface of the second bonding layer on the first back face of the first chip; and
forming external connection bumps connected to the plurality of protruded metal pillars on the bottom surfaces of the plurality of protruded metal pillars.

2. The method according to claim 1, wherein a metal layer is arranged on the upper surface of the carrier plate, wherein the metal layer is used as the first bonding layer, and the plurality of protruded metal pillars are formed on an upper surface of the metal layer.

3. The method according to claim 2, wherein the second bonding layer is made of a metal or a dielectric material.

4. The method according to claim 3, wherein in case that the second bonding layer is made of the metal, the second bonding layer and the metal layer are made of a same material.

5. The method according to claim 1, wherein a metal layer, metal pillars protruded from an upper surface of the metal layer, and a photosensitive polymer layer on an upper surface of the metal layer and wrapping lower side walls of the metal pillars are arranged on the upper surface of the carrier plate, wherein the photosensitive polymer layer is used as the first bonding layer.

6. The method according to claim 2, wherein a temporary bonding layer is further formed between the metal layer and the carrier plate, wherein the temporary bonding layer is removed while removing the carrier plate and the first bonding layer.

7. The method according to claim 1, wherein a temporary bonding layer and metal pillars protruded from an upper surface of the temporary bonding layer are arranged on the upper surface of the carrier plate, wherein the temporary bonding layer is used as the first bonding layer.

8. The method according to claim 7, wherein the temporary bonding layer is made of silicon oxide.

9. The method according to claim 5, wherein the second bonding layer is made of a metal.

10. The method according to claim 1, further comprising: forming pseudo-external connection bumps on the second bonding layer on the first back face of the first chip.

11. The method according to claim 10, wherein the pseudo-external connection bumps are formed on a surface of the second bonding layer on the first back face of the first chip while forming the external connection bumps connected to the plurality of protruded metal pillars on the bottom surfaces of the plurality of protruded metal pillars.

12. The method according to claim 11, wherein prior to forming the external connection bumps and the pseudo-external connection bumps, the method further comprises:
forming a polymer layer on a back face of the first molding layer, wherein a first opening exposing the surface of the second bonding layer on the first back face of the first chip and a second opening exposing the bottom surfaces of the plurality of protruded metal pillars are defined in the polymer layer; wherein the pseudo-external connection bumps are formed in the first opening, the external connection bumps are formed in the second opening, and the pseudo-external connection bumps and the external connection bumps all protrude from a surface of the polymer layer.

13. The method according to claim 1, wherein the method further comprises forming a redistribution layer on the first molding layer, wherein the redistribution layer is electrically connected to the plurality of first external connection terminals and the plurality of protruded metal pillars; and
wherein the plurality of second external connection terminals on the second chip are electrically connected to the plurality of first external connection terminals and the plurality of protruded metal pillars via the redistribution layer.

14. A package structure, comprising:
a carrier plate;
a first bonding layer and a plurality of protruded metal pillars on an upper surface of the carrier plate;
a first chip comprising a first functional face and a first back face that are opposite to each other, wherein a plurality of first external connection terminals are arranged on the first functional face, and a second bonding layer is arranged on the first back face, wherein the second bonding layer on the first back face of the first chip is bonded to the first bonding layer on the upper surface of the carrier plate;
a first molding layer configured to mold the first chip and the plurality of protruded metal pillars, wherein the first molding layer exposes top surfaces of the plurality of first external connection terminals and the plurality of protruded metal pillars;
a second chip comprising a second functional face and a second back face that are opposite to each other, wherein second external connection terminals are arranged on the functional face, and the second chip is flip-mounted on the first molding layer, wherein the second external connection terminals on the second chip are electrically connected to the top surfaces of the plurality of first external connection terminals and the plurality of protruded metal pillars; and
a second molding layer configured to mold the second chip on the first molding layer.

15. The package structure according to claim 14, wherein a metal layer is arranged on the upper surface of the carrier plate, wherein the metal layer is used as the first bonding layer, and the plurality of protruded metal pillars are formed on an upper surface of the metal layer.

16. The package structure according to claim 15, wherein the second bonding layer is made of a metal or a dielectric material; and in case that the second bonding layer is made of the metal, the second bonding layer and the metal layer are made of a same material.

17. The package structure according to claim 14, wherein a metal layer, metal pillars protruded from an upper surface of the metal layer, and a photosensitive polymer layer on an upper surface of the metal layer and wrapping lower side walls of the metal pillars are arranged on the upper surface of the carrier plate, wherein the photosensitive polymer layer is used as the first bonding layer.

18. The package structure according to claim 15, wherein a temporary bonding layer is formed between the metal layer and the carrier plate.

19. The package structure according to claim 14, wherein a temporary bonding layer and metal pillars protruded from an upper surface of the temporary bonding layer are arranged on the upper surface of the carrier plate, wherein the temporary bonding layer is used as the first bonding layer.

20. The package structure according to claim 19, wherein the temporary bonding layer is made of silicon oxide, and wherein the second bonding layer is made of a metal.
